(19) United States
(12) Patent Application Publication
(10) Pub. No.: US 2025/0140728 A1
(43) Pub. Date: May 1, 2025

(54) SEMICONDUCTOR PACKAGE WITH REDISTRIBUTION STRUCTURE

(71) Applicant: SAMSUNG ELECTRONICS CO., LTD., Suwon-si (KR)

(72) Inventors: Taehoon Lee, Suwon-si (KR); Dahee Kim, Suwon-si (KR); Gyujin Choi, Suwon-si (KR)

(21) Appl. No.: 18/898,033

(22) Filed: Sep. 26, 2024

(30) Foreign Application Priority Data
Oct. 25, 2023 (KR) 10-2023-0144178

(51) Int. Cl. H01L 23/00; H01L 23/498

(52) U.S. Cl. CPC H01L 24/20; H01L 23/49822; H01L 2224/2101; H01L 2224/214; H01L 2224/221

(57) ABSTRACT

An example semiconductor package includes a redistribution structure, including a first surface and a second surface, and a semiconductor chip on the first surface of the redistribution structure. The redistribution structure includes a plurality of first conductive lines, including a first signal line, and a plurality of second conductive lines at a vertical level different from the plurality of first conductive lines. The plurality of second conductive lines include a ground line electrically insulated from the first signal line. The ground line includes an opening extending through the ground line at a position vertically overlapping the first signal line and a venting hole communicating with a first end portion of the opening. The first end portion of the opening has a first width in a first horizontal direction. The venting hole has a second width smaller than the first width in the first horizontal direction.

### CROSS-REFERENCE TO RELATED APPLICATION

This application claims priority under 35 U.S.C. § 119 to Korean Patent Application No. 10-2023-0144178, filed on Oct. 25, 2023, in the Korean Intellectual Property Office, the disclosure of which is incorporated by reference herein in its entirety.

### BACKGROUND

With the rapid development of the electronic industry and the demands of users, electronic devices are becoming smaller and lighter, and accordingly, semiconductor devices, which are core components of electronic devices, are required to be highly integrated. A semiconductor package with connection terminals with secured connection reliability has been designed for a highly integrated semiconductor chip with an increased number of connection terminals for input/output (I/O). For example, a fan-out semiconductor package such as a fan-out panel level package has been developed to increase the gap between connection terminals in order to prevent interference therebetween.

### SUMMARY

The present disclosure relates to semiconductor packages, including a semiconductor package having improved reliability of a redistribution structure, and a semiconductor package capable of simplifying a process of forming a redistribution structure. For example, the present disclosure relates to a fan-out panel level package (FOPLP).

In some implementations, a semiconductor package includes a redistribution structure including a first surface and a second surface, and a semiconductor chip on the first surface of the redistribution structure, wherein the redistribution structure includes a plurality of first conductive lines including a first signal line, and a plurality of second conductive lines arranged at a vertical level different from a vertical level of the plurality of first conductive lines and including a ground line electrically insulated from the first signal line, wherein the ground line includes an opening passing through the ground line at a position vertically overlapping the first signal line and including a first end portion having a first width in a first horizontal direction, and a venting hole communicating with the first end portion of the opening and having a second width smaller than the first width in the first horizontal direction.

In some implementations, a semiconductor package includes a redistribution structure including a first surface and a second surface, a semiconductor chip on the first surface of the redistribution structure, and an external connection terminal on the second surface of the redistribution structure, wherein the redistribution structure includes a plurality of first conductive lines arranged at a first vertical level lower than a vertical level of the first surface of the redistribution structure, a first redistribution insulation layer covering bottom surfaces of the plurality of first conductive lines, a plurality of second conductive lines arranged on a bottom surface of the first redistribution insulation layer and arranged at a second vertical level lower than the first vertical level, and a second redistribution insulation layer arranged on a bottom surface of the first redistribution insulation layer and covering bottom surfaces of the plurality of second conductive lines, wherein at least one second conductive line from among the plurality of second conductive lines includes an opening passing through the at least one second conductive line and including a first end portion having a first width in a first horizontal direction, and a venting hole communicating with the first end portion of the opening and having a second width smaller than the first width of the opening.

In some implementations, a semiconductor package includes a first redistribution structure, a semiconductor chip on a top surface of the first redistribution structure, a connection structure provided on the top surface of the semiconductor package and arranged on at least one side of the semiconductor chip, a second redistribution structure arranged on the semiconductor chip and the connection structure, and an external connection terminal provided on a bottom surface of the first redistribution structure, wherein the first redistribution structure includes a plurality of first conductive lines including a first signal line, and a first redistribution insulation layer covering the plurality of first conductive lines and including a photosensitive polymer, a plurality of second conductive lines arranged at a vertical level lower than the plurality of first conductive lines and including a ground line electrically insulated from the first signal line, and a second redistribution insulation layer covering the plurality of second conductive lines and including a photosensitive polymer, wherein the ground line includes an opening passing through the ground line at a position vertically overlapping the first signal line and including a first end portion having a first width in a first horizontal direction, and a venting hole communicating with the first end portion of the opening and having a second width smaller than the first width in the first horizontal direction, wherein the ground line includes a pair of signal line patterns, and the opening vertically overlaps both of the pair of signal line patterns.

### BRIEF DESCRIPTION OF THE DRAWINGS

Implementations of the present disclosure will be more clearly understood from the following detailed description taken in conjunction with the accompanying drawings.

FIG. 1 is a cross-sectional view illustrating an example of a semiconductor package.

FIG. 2 is an example enlarged view of a portion A of FIG. 1.

FIGS. 3 to 11 are example plan views illustrating various planar shapes of a second ground line included in a semiconductor package.

FIGS. 12A and 12B are example graphs illustrating a frequency of occurrence of defects in a semiconductor package.

FIG. 13 is a cross-sectional view illustrating an example of a semiconductor package.

FIGS. 14 to 18, 19A to 19E, and 20 are schematic cross-sectional views illustrating an example of a method of manufacturing a semiconductor package.

### DETAILED DESCRIPTION

Hereinafter, implementations of the present disclosure will be described in detail with reference to the accompanying drawings.

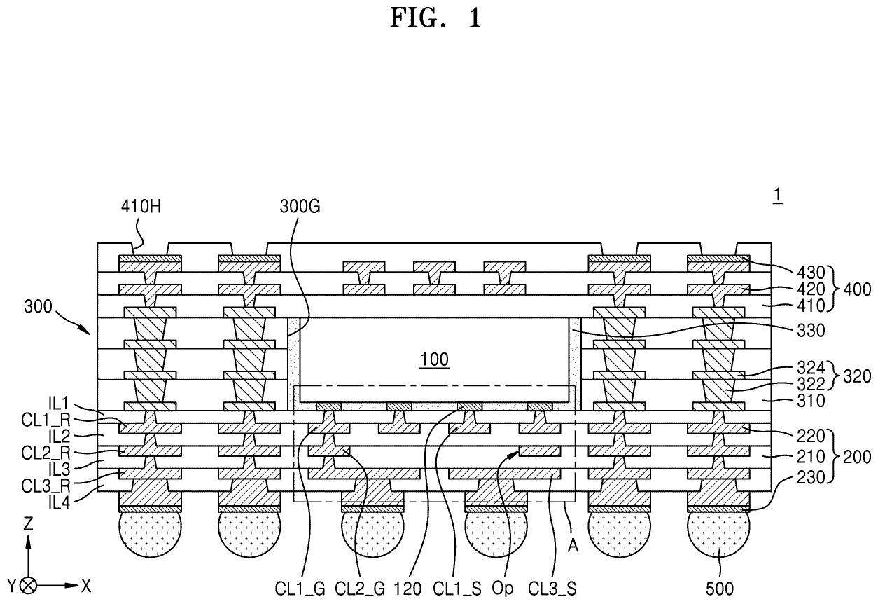

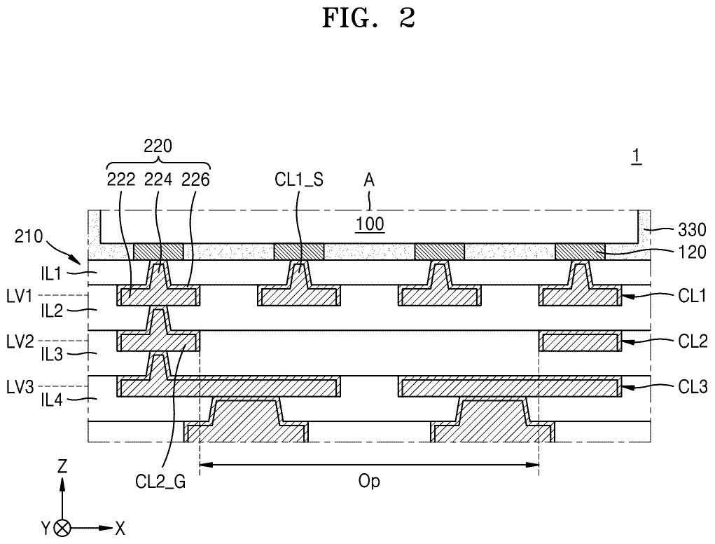

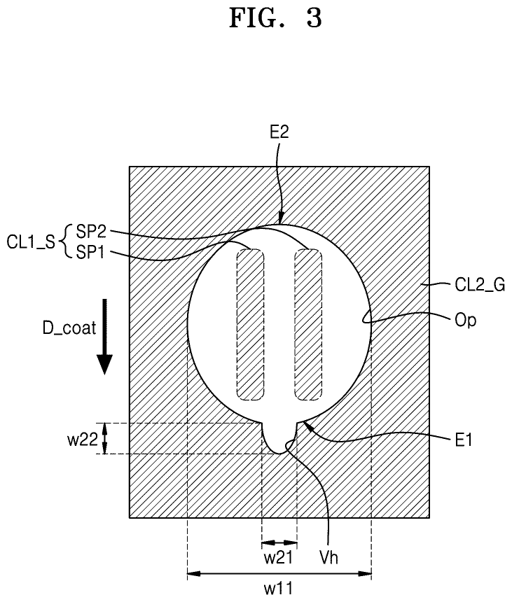

FIG. 1 is a cross-sectional view illustrating an example of a semiconductor package 1. FIG. 2 is an example enlarged view of a portion A of FIG. 1. FIGS. 3 to 11 are example plan views illustrating various planar shapes of a second ground line GL2_G included in a semiconductor package I.

Referring to FIGS. 1 to 11, a semiconductor package 1 may include a semiconductor chip 100, a first redistribution structure 200, a connection structure 300, and a second redistribution structure 400. The semiconductor chip 100 may be arranged on the first redistribution structure 200, the connection structure 300 may be arranged on the first redistribution structure 200 to surround the semiconductor chip 100, and the second redistribution structure 400 may be arranged on the semiconductor chip 100 and the connection structure 300. The connection structure 300 may electrically connect the first redistribution structure 200 and the second redistribution structure 400 to each other. The semiconductor package 1 may be a fan-out type panel level package (FOPLP).

In some implementations, the first redistribution structure 200 and the second redistribution structure 400 may be formed by a redistribution process. In some implementations, the semiconductor package 1 may be formed in a chip-first manner in which the connection structure 300 and the semiconductor chip 100 are first formed, and then the first redistribution structure 200 and the second redistribution structure 400 are formed.

The first redistribution structure 200 may include a first redistribution insulation layer 210 and a plurality of first redistribution patterns 220. The first redistribution insulation layer 210 may be arranged to surround the plurality of first redistribution patterns 220. In some implementations, the first redistribution structure 200 may include a plurality of stacked first redistribution insulation layers 210.

In some implementations, the first redistribution insulation layer 210 may include a photosensitive polymer. For example, the first redistribution insulation layer 210 may be formed from a photo imageable dielectric (PID) or photosensitive polyimide (PSPI), or may be formed of a build-up film such as an Ajinomoto Build-up Film (ABF).

The plurality of first redistribution patterns 220 may include a plurality of first redistribution line patterns 222, a plurality of first redistribution vias 224, and a plurality of first redistribution seed layers 226. The plurality of first redistribution patterns 220 may be, for example, a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru) or the like, or a metal alloy thereof, but is not limited thereto. In some implementations, the first redistribution line pattern 222 and the first redistribution via 224 may be made of the same material, and the first redistribution seed layer 226 may be made of a material different from each of the first redistribution line pattern 222 and the first redistribution via 224. In some implementations, the first redistribution line pattern 222 and the first redistribution via 224 may include copper or a copper alloy, and the first redistribution seed layer 226 may include titanium or titanium nitride.

A plurality of the first redistribution vias 224 may pass through at least one first redistribution insulation layer 210 to be connected to be in contact with some of the plurality of first redistribution line patterns 222, respectively. In some implementations, each of the plurality of first redistribution vias 224 may have a tapered shape extending with a narrower horizontal width from the lower side to the upper side. For example, the plurality of first redistribution vias 224 may have a wider horizontal width in a direction away from at least one semiconductor chip 100.

In some implementations, at least some of the plurality of first redistribution line patterns 222 may be formed integrally with some of the plurality of first redistribution vias 224. For example, the first redistribution line pattern 222 and the first redistribution via 224 contacting the top surface of the first redistribution line pattern 222, that is, the first redistribution via 224 extending from the top surface of the first redistribution line pattern 222, may be formed together to be integrated with each other. For example, each of the plurality of first redistribution vias 224 may have a narrower horizontal width while moving away from the integrated first redistribution line pattern 222. The first redistribution seed layer 226 may cover the first redistribution line pattern 222 and the first redistribution via 224 integrating with each other.

In some implementations, the plurality of first redistribution line patterns 222 may include a plurality of first conductive lines CL1 arranged on a first vertical level LV1, a plurality of second conductive lines CL2 arranged at a second vertical level LV2 lower than the plurality of first conductive lines CL1, and a plurality of third conductive lines CL3 arranged at a third vertical level LV3 lower than the plurality of second conductive lines CL2.

Here, the first vertical level LV1 may indicate a level lower than that of the top surface of the first redistribution structure 200. In addition, the second vertical level LV2 may indicate a lower level than that of the upper surface of the first redistribution structure 200, and the vertical distance from the semiconductor chip 100 to the second vertical level LV2 may be longer than the vertical distance from the semiconductor chip 100 to the first vertical level LV1. In addition, the third vertical level LV3 may indicate a lower level than that of the upper surface of the first redistribution structure 200, and the vertical distance from the semiconductor chip 100 to the third vertical level LV3 may be longer than the vertical distance from the semiconductor chip 100 to the second vertical level LV2.

The plurality of first conductive lines CL1 may include a first signal line CL1_S. The first signal line CL1_S may include a line pattern for supplying a signal to the semiconductor chip 100. In some implementations, the first signal line CL1_S may be composed of lines of various widths and shapes designed to supply a high-speed signal to the semiconductor chip 100.

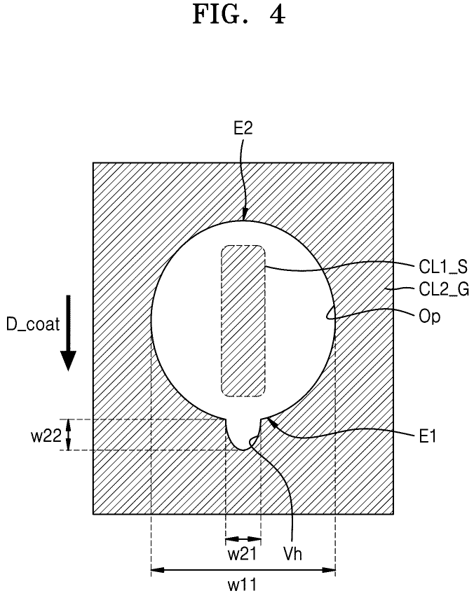

In some implementations, the first signal line CL1_S may include a pair of signal line patterns SP1 and SP2, as illustrated in FIG. 3. The pair of signal line patterns SP1 and SP2 may be arranged to be spaced apart from each other in a lateral direction at a first vertical level and may extend parallel to each other. In some implementations, the pair of signal line patterns SP1 and SP2 may include a differential signal pair for delivering a high-speed signal to the semiconductor chip 100. For example, the pair of signal line patterns SP1 and SP2 may include a supply line pair of all signals implemented as differential signal pairs, including clock pairs, data, commands, addresses, etc., transmitted to the semiconductor chip 100. In some implementations, as illustrated in FIG. 4, the first signal line CL1_S may include a single signal line pattern instead of the pair of signal line patterns SP1 and SP2. In some implementations, the first signal line CL1_S may include a single signal line pattern in addition to the pair of signal line patterns SP1 and SP2.

The plurality of first conductive lines CL1 may further include a first ground line CL1_G and a first redistribution line CL1_R. The first ground line CL1_G and the first redistribution line CL1_R may be arranged to be spaced apart from the first signal line CL1_S in the lateral direction at the first vertical level LV1. For example, the first ground line CL1_G may be configured such that a ground voltage is applied thereto and the first redistribution line CL1_R may be configured such that a power voltage or another signal voltage is applied thereto.

A plurality of second conductive lines CL2 may include a second ground line CL2_G. The second ground line CL2_G may be arranged at a second vertical level LV2. The second ground line CL2_G may include an opening Op penetrating the inside of the second ground line CL2_G, and the opening Op may be arranged at a position vertically overlapping the first signal line CL1_S. For example, the opening Op may be arranged at a position vertically overlapping the pair of signal line patterns SP1 and SP2 of the first signal line CL1_S. As shown in FIG. 3, the opening Op may have a circular or elliptical planar shape, and the opening Op may be arranged at a position vertically overlapping the pair of signal line patterns SP1 and SP2 (indicated by dotted lines in FIG. 3) arranged at a vertical level higher than the opening Op.

A venting hole Vh may be arranged in the first end portion E1 of the opening Op. The venting hole Vh may penetrate the inside of the second ground line CL2_G and may communicate with the first end portion E1 of the opening Op. A portion of the first redistribution insulation layer 210 may be filled in the opening Op and the venting hole Vh. The venting hole Vh may act as a degas path from the opening Op in an operation of filling the first redistribution insulation layer 210 inside the opening Op by a coating process, and thus, air may be minimized or prevented from being trapped in the opening Op.

In some implementations, the first redistribution insulation layer 210 may be formed by applying or coating a viscous photosensitive polymer material on the first redistribution line pattern 220 and curing the photosensitive polymer material by a subsequent curing process. On the sidewall of the opening Op, a step may occur due to a relatively large height of the first redistribution line pattern 220, and the inside of the opening Op is not completely filled with the photosensitive polymer material, and air may be trapped, so that air may remain in the photosensitive polymer material. In this case, a defect may occur when the subsequent first redistribution line pattern 220 is formed. However, a venting hole Vh is placed at the first end portion E1 of the opening Op, and thus, air may be minimized or prevented from being trapped inside the opening Op.

In some implementations, the venting hole Vh may have a width narrower than the first end portion E1 of the opening Op. The first end portion E1 of the opening Op may have a first width w11 in the first horizontal direction X, the venting hole Vh may have a second width w21 in the first horizontal direction X, and the second width w21 may be smaller than the first width w11.

For example, when the opening Op has a circular horizontal cross-section as illustrated in FIG. 3, the first width w11 may correspond to the maximum width of the opening Op, for example, the diameter of the opening Op. The second width w21 of the venting hole Vh may indicate a width of a portion of the venting hole Vh communicating with and arranged adjacent to the first end portion E1 of the opening Op.

In some implementations, the first width w11 may range from about 50 micrometers to about 1000 micrometers, but is not limited thereto. In some implementations, the second width w21 may have a range of about 15% to about 30% of the first width w11. For example, when the second width w21 is smaller than about 15% of the first width w11, there is no degassing effect from the opening Op, and when the second width w21 is wider than about 30% of the first width w11, the amount of air remaining trapped in the venting hole Vh increases, so that the total amount of air trap reduction may not be large.

In some implementations, the venting hole Vh may have a third width w22 in the second horizontal direction Y crossing the first horizontal direction X, and the third width w22 may be about 50% or more of the second width w21. For example, when the third width w22 of the venting hole Vh in the second horizontal direction Y is smaller than about 50% of the second width w21 in the first horizontal direction X, it may be difficult to sufficiently discharge air in the opening Op through the venting hole Vh.

In some implementations, the planar cross-sectional area of the venting hole Vh may range from about 5% to about 30% of the planar cross-sectional area of the opening Op. When the planar cross-sectional area of the venting hole Vh is less than about 5% of the planar cross-sectional area of the opening Op, the degassing effect from the opening Op may not be sufficiently achieved. When the planar cross-sectional area of the venting hole Vh is greater than about 30% of the planar cross-sectional area of the opening Op, the residual amount of air trapped in the venting hole Vh rather increases, so that the total amount of air trap reduction may not be large.

In some implementations, the venting hole Vh may be arranged to communicate with the first end portion E1 of the opening Op, and the first end portion E1 of the opening Op may indicate a portion of the opening Op in which the photosensitive polymer material is finally filled in the opening Op in the process of applying or coating photosensitive polymer materials. For example, as illustrated in FIG. 3, the opening Op may include a first end portion E1 and a second end portion E2 opposite to the first end portion E1, and a photosensitive polymer material may be coated or applied in a coating direction D_coat from the second end portion E2 of the opening Op toward the first end portion E1 thereof.

The venting hole Vh communicates with the first end portion E1 of the opening Op in which the photosensitive polymer material is finally filled in the opening Op in the coating direction D_coat, so that the photosensitive polymer material completely fills the inside of the opening Op without remaining air, all air is discharged through the venting hole Vh, and the inside of the venting hole Vh may also be completely filled by the photosensitive polymer material or only a little amount of air may remain inside the venting hole Vh.

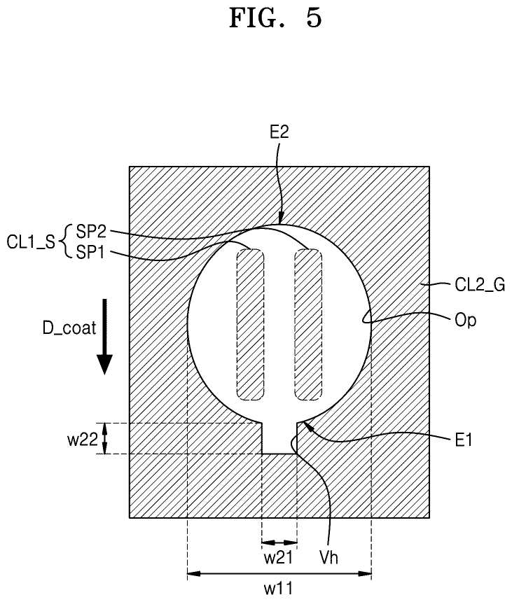

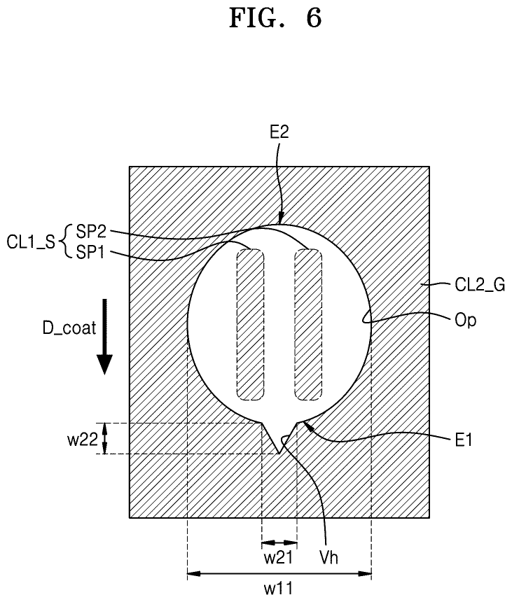

In some implementations, as illustrated in FIG. 3, the opening Op may have a circular or elliptical planar shape, and the venting hole Vh may have an elliptical or semicircular planar shape. In some implementations, as illustrated in FIG. 5, the venting hole Vh may have a square or rectangular planar shape. In some implementations, as illustrated in FIG. 6, the venting hole Vh may have a triangular planar shape.

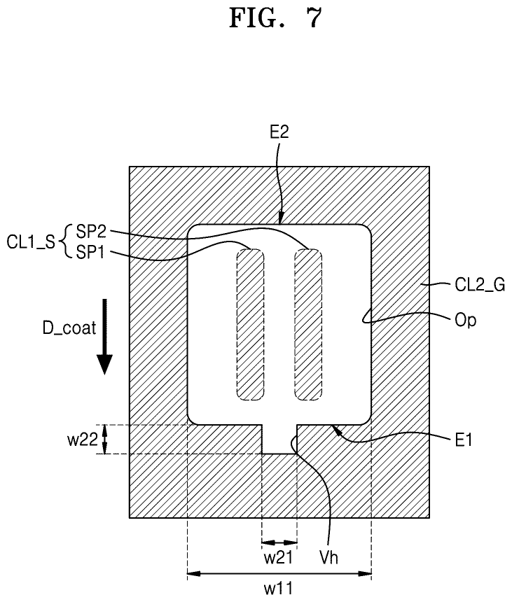

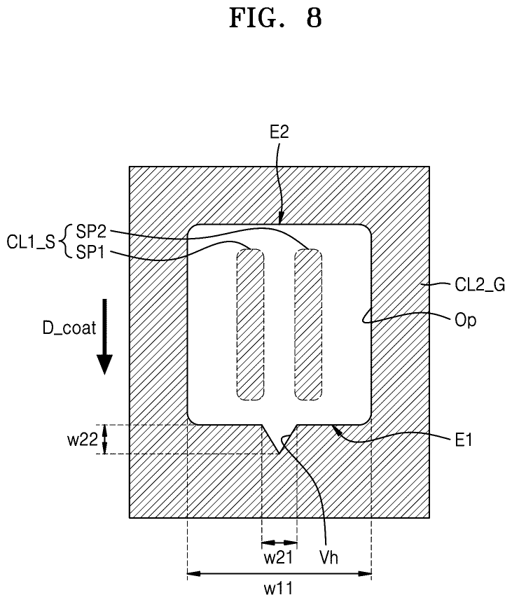

In some implementations, as illustrated in FIG. 7, the opening Op may have a rectangular or corner-rounded rectangular planar shape, and the venting hole Vh may have a square or rectangular planar shape. In some implementations, as illustrated in FIG. 8, the opening Op may have a rectangular or corner-rounded rectangular planar shape, and the venting hole Vh may have a triangular planar shape. In some implementations, the venting hole Vh may have a polygonal or rounded polygonal planar shape.

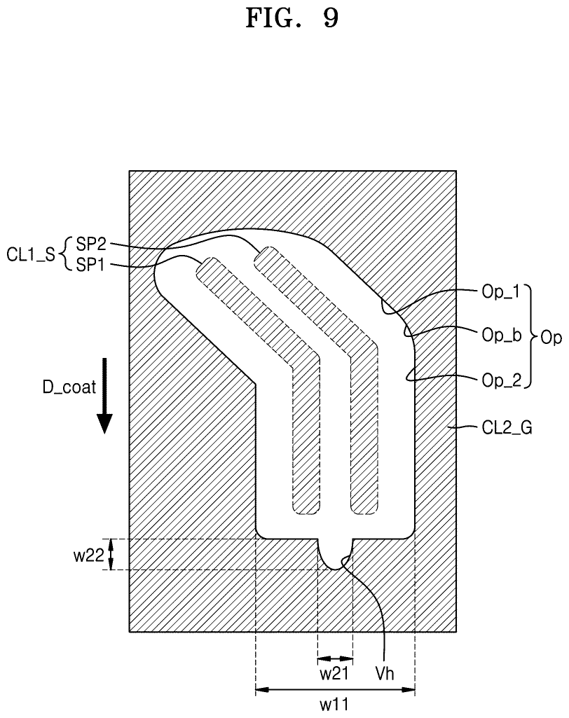

In some implementations, the opening Op may have an atypical planar shape as illustrated in FIG. 9.

The first signal line CL1_S may include the pair of signal line patterns SP1 and SP2, and each of the pair of signal line patterns SP1 and SP2 may have a planar shape including a first line portion extending in a first direction, a second line portion extending in a second direction and connected to the first line portion, and an inflection portion between the first line portion and the second line portion.

In some implementations, as illustrated in FIG. 9, the opening Op may be arranged to surround the first signal line CL1_S when viewed in a plan view. For example, the sidewall of the opening Op may surround the first signal line CL1_S and may be arranged to be laterally spaced apart from the first signal line CL1_S. The opening Op may have a planar shape including a first portion Op_1 extending in a first direction and a second portion Op_2 extending in a second direction and communicating with the first portion Op_1. A bending portion Op_b may be formed between the first portion Op_1 and the second portion Op_2.

In some implementations as illustrated in FIG. 9, the venting hole Vh may have an elliptical or semicircular planar shape, but in some implementations, the venting hole Vh may have a square, rectangular, or triangular planar shape.

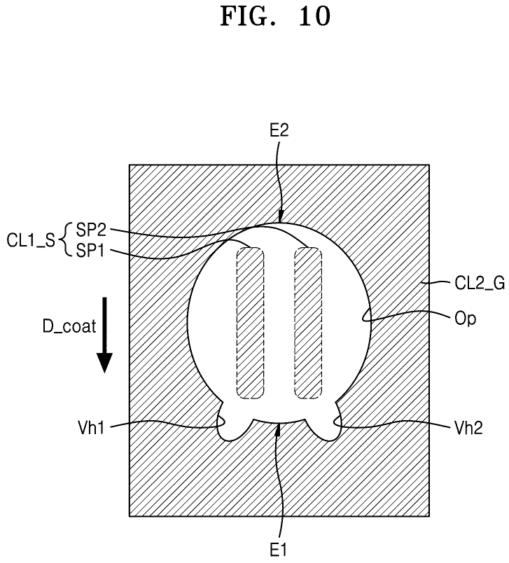

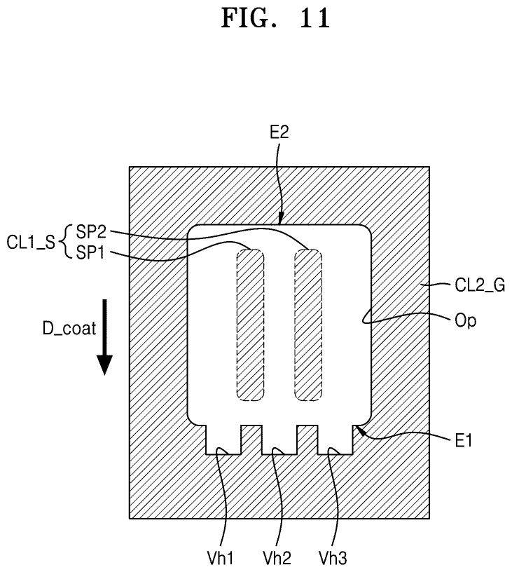

In some implementations, a plurality of venting holes Vh may be formed to communicate with one opening Op. As illustrated in FIG. 10, the opening Op may have a circular or elliptical planar shape, and a first venting hole Vh1 and a second venting hole Vh2 each having an elliptical or semicircular planar shape may be arranged to be spaced apart from each other so as to communicate with the first end portion E1 of the opening Op. As illustrated in FIG. 11, the opening Op may have a rectangular or corner-rounded rectangular planar shape, and a first venting hole Vh1, a second venting hole Vh2, and a third venting hole Vh3 each having a rectangular or corner-rounded rectangular planar shape may be arranged to be spaced apart from each other so as to communicate with the first end portion E1 of the opening Op.

Although the opening Op and the venting hole Vh with various planar shapes are illustrated in FIGS. 3 to 11, the shapes of the opening Op and the venting hole Vh according to the present disclosure are not limited thereto. It will be understood that the opening Op may have various structured and atypical planar shapes having a closed loop shape, and the venting hole Vh may have various structured and atypical planar shapes connected to one end of the opening Op and having a narrower width than the opening Op.

Referring back to FIG. 1, the plurality of second conductive lines CL2 may further include a second redistribution line CL2_R. The second redistribution line CL2_R may be electrically connected to the first redistribution line CL1_R.

The plurality of third conductive lines CL3 may further include a third signal line CL3_S and a third redistribution line CL3_R. The third redistribution line CL3_R may be electrically connected to the second redistribution line CL2_R. In some implementations, the third signal line CL3_S may be arranged to vertically overlap the opening Op of the second ground line CL2_G. In this case, the third signal line CL3_S may vertically overlap a portion of the first redistribution insulation layer 210 filling the inside of the opening Op of the second ground line CL2_G. In some implementations, the third signal line CL3_S may be arranged at a position that does not vertically overlap the opening Op of the second ground line CL2_G.

In FIG. 1, a three-layer wiring layer structure in which the redistribution line pattern 220 includes the plurality of first conductive lines CL1, the plurality of second conductive lines CL2, and the plurality of third conductive lines CL3 has been illustrated, but in some implementations, the first redistribution structure 200 may have a four-layer wiring layer structure or a five-layer wiring layer structure, and for example, a plurality of fourth conductive lines or a plurality of fifth conductive lines may be further formed at a vertical level lower than the third vertical level LV3. When the first redistribution structure 200 has a four-layer wiring layer structure or a five-layer wiring layer structure, at least one of the plurality of fourth conductive lines or the plurality of fifth conductive lines may include an additional ground line having an opening. The additional ground line may include an opening Op and a venting hole Vh with various planar shapes illustrated as illustrated in FIGS. 3 to 11.

The first redistribution structure 200 may further include a plurality of bottom surface connection pads 230 arranged on the bottom surface of the first redistribution structure 200. Each of the plurality of bottom surface connection pads 230 may be connected to the bottom surface of the first redistribution line pattern 222. The plurality of bottom connection pads 230 may include nickel (Ni) or gold (Au). A plurality of external connection terminals 500 may be attached to the plurality of bottom surface connection pads 230. The plurality of external connection terminals 500 may connect the semiconductor package I to the outside. The plurality of external connection terminals 500 may include solder balls or solder bumps.

A semiconductor chip 100 may be attached on the first redistribution structure 200. The semiconductor chip 100 may be mounted on the first redistribution structure 200 in a flip chip manner. The semiconductor chip 100 may be electrically connected to the redistribution line pattern 220 of the first redistribution structure 200 through a lower chip pad 110.

In some implementations, the semiconductor chip 100 may be a memory chip or a logic chip. The memory chip may be, for example, a volatile memory chip such as dynamic random access memory (DRAM) or static random access memory (SRAM), or a nonvolatile memory chip such as NAND flash memory, phase-change random access memory (PRAM), magnetoresistive random access memory (MRAM), ferroelectric random access memory (FeRAM), or resistive random access memory (RRAM). In addition, the logic chip may be, for example, a microprocessor, an analog device, or a digital signal processor.

The connection structure 300 may have a mounting space 300G in which the semiconductor chip 100 is arranged, and may include a base layer 310 and a plurality of connection vias 320. The plurality of connection vias 320 may penetrate the base layer 310. The connection structure 300 may be a printed circuit board (PCB), a ceramic substrate, a wafer for manufacturing a package, or an interposer. The connection structure 300 may include two or more stacked base layers 310, but may include a single base layer 310 in some implementations. For example, the connection structure 300 may be a multi-layer printed circuit board.

The base layer 310 may be formed of at least one material selected from phenol resin, epoxy resin, and polyimide. The base layer 310 may include at least one material selected from frame retardant 4 (FR-4), tetrafunctional epoxy, polyphenylene ether, epoxy/polyphenylene oxide, bismaleimide triazine (BT), Thermount, Cyanate ester, polyimide and liquid crystal polymer.

In some implementations, the plurality of connection vias 320 may include an electrolytically deposited (ED) copper foil, a rolled-annealed (RA) copper foil, stainless steel foil, aluminum foil, ultra-thin copper foils, sputtered copper, copper alloys, etc. Each of the plurality of connection vias 320 may include a via portion 322 penetrating the base layer 310 and a connection pattern portion 324 arranged on the top surface of the base layer 310 and integrally connected to the via portion 322.

The semiconductor package 1 may further include a filling insulation layer 330 filling the mounting space 300G. The filling insulation layer 330 may fill a space between the semiconductor chip 100 and the base layer 310 arranged in the mounting space 300G. For example, the filling insulation layer 330 may be formed from thermosetting resins such as epoxy resins, thermoplastic resins such as polyimide, or resins containing reinforcements such as inorganic fillers, specifically Ajinomoto Build-up Film (ABF), FR-4, BT, etc. Alternatively, the filling insulation layer 330 may be formed from a molding material such as EMC or a photosensitive material such as photoimagable encapsulant (PIE). In some implementations, a portion of the filling insulation layer 330 may be formed of an insulation material such as a silicon oxide layer, a silicon nitride layer, or a silicon oxynitride layer.

The second redistribution structure 400 may include a second redistribution insulation layer 410 and a plurality of second redistribution patterns 420. The plurality of second redistribution patterns 420 may include a plurality of second redistribution line patterns, a plurality of second redistribution vias, and a plurality of second redistribution seed layers. The second redistribution insulation layer 410 and the plurality of second redistribution patterns 420 included in the second redistribution structure 400 are generally similar to the first redistribution insulation layer 210 and the plurality of first redistribution patterns 220 included in the first redistribution structure 200, and the redundant description may be omitted.

The second redistribution structure 400 may further include a plurality of top surface connection pads 430 arranged on the top surface of the second redistribution structure 400. The plurality of top surface connection pads 430 may include nickel (Ni) or gold (Au). The second redistribution insulation layer 410 includes an opening 410H in an upper portion of the second redistribution insulation layer 410, and the top surface of each of the plurality of top surface connection pads 430 may be exposed by the opening 410H.

In general, in the process of forming a redistribution structure, a photosensitive polymer material is applied or coated on the top surface of the redistribution line pattern including copper, and a redistribution insulation layer is formed by a subsequent curing process. When a photosensitive polymer material is applied to a redistribution line pattern having a relatively large opening, a step may occur due to a relatively high height of the redistribution line pattern. A difference in coating speed may occur due to the step, and the inside of the opening may not be completely filled by the photosensitive polymer material, and air may be trapped, and thus air may remain in the photosensitive polymer material. The trapped air may cause voids or cracks in the redistribution insulation layer, or may cause a defect in a subsequent redistribution line pattern.

However, the parasitic capacitance of the signal line may be reduced as the opening Op is formed in the second ground line CL2_G of a portion vertically overlapping the first signal line CL1_S. In addition, the venting hole Vh is formed in the first end portion E1 of the opening Op, and thus, air may be minimized or prevented from being trapped in the opening Op. Therefore, the semiconductor package 1 may have excellent reliability.

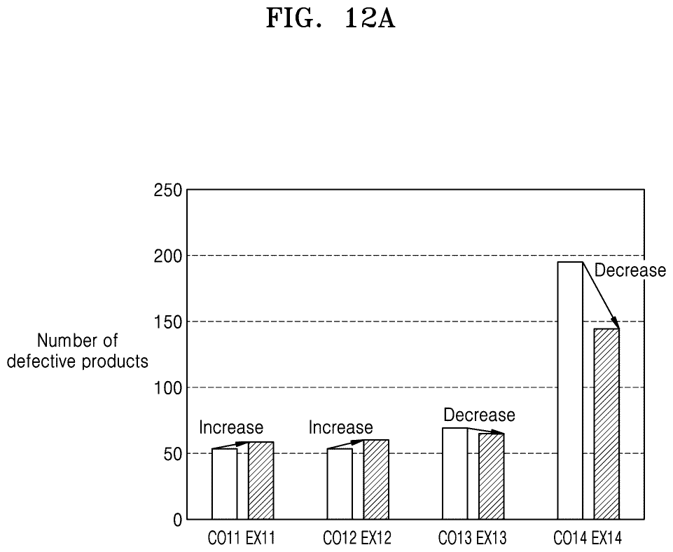

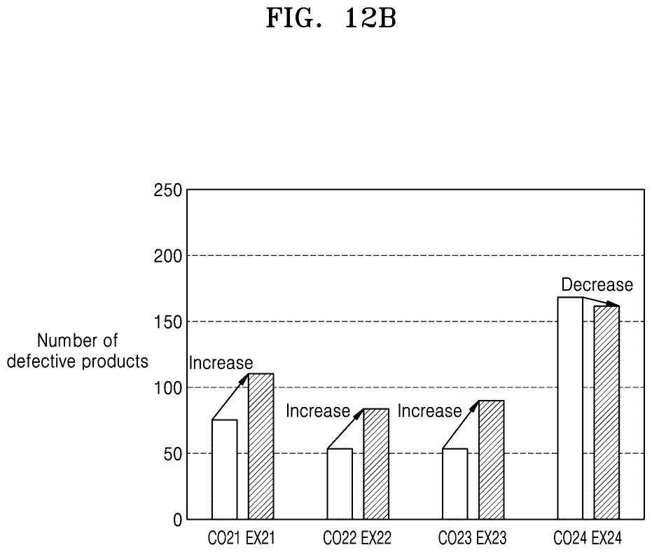

FIGS. 12A and 12B are example graphs illustrating the frequency of occurrence of defects in a semiconductor package.

Referring to FIG. 12A, Comparative Examples 1 to 4 CO11, CO12, CO13, and CO14 may be semiconductor packages in which a large conductive line in a first redistribution structure includes an opening having a relatively wide width. Examples 1 to 4 EX11, EX12, EX13, and EX14 may be semiconductor packages each further including a venting hole communicating with the opening in each of the structures corresponding to Comparative Examples 1 to 4 CO11, CO12, CO13, and CO14. In Example 1 EX11, the width of the venting hole is about 8% of the width of the opening, in Example 2 EX12, the width of the venting hole is about 9% of the width of the opening, in Example 3 EX13, the width of the venting hole is about 11% of the width of the opening, and in Example 4 EX14, the width of the venting hole is about 15% of the width of the opening. The number of defective products corresponds to the number of semiconductor packages in which air traps having a reference size or more remain in the opening.

As illustrated in FIG. 12A, Example 1 EX11 and Example 2 EX12 represent a slightly increased number of defective products in comparison to Comparative Example 1 CO11 and Comparative Example 2 CO12, whereas Example 3 EX13 represents a slightly decreased number of defective products in comparison to Comparative Example 3 CO13, and Example 4 EX14 represents a significantly reduced number of defective products in comparison to Comparative Example 4 CO14, for example, the number of defective products reduced by about 25%. Accordingly, it may be confirmed that, when the width of the venting hole is about 15% or more of the width of the opening, the air trap may be prevented in the opening. When the width of the venting hole is less than about 10% of the width of the opening, it may be assumed that the effect of preventing air trap by the venting hole is hardly exhibited or the amount of air remaining trapped in the relatively small venting hole is rather increased.

Referring to FIG. 12B, Comparative Examples 5 to 8 CO21, CO22, CO23, and CO24 may be semiconductor packages in which a large conductive line in a first redistribution structure includes an opening having a relatively wide width. Comparative Examples 5 to 8 CO21, CO22, CO23, and CO24 may have structures similar to Comparative Examples 1 to 4 CO11, CO12, CO13, and CO14, except for signal line designs, respectively. Examples 5 to 8 EX21, EX22, EX23, and EX24 may be semiconductor packages each further including a venting hole communicating with the opening in each of the structures corresponding to Comparative Examples 5 to 8 CO21, CO22, CO23, and CO24. In Example 5 EX21, the width of the venting hole is about 8% of the width of the opening, in Example 6 EX22, the width of the venting hole is about 9% of the width of the opening, in Example 7 EX23, the width of the venting hole is about 11% of the width of the opening, and in Example 8 EX24, the width of the venting hole is about 15% of the width of the opening.

As illustrated in FIG. 12B, Example 5 EX21, Example 6 EX22, and Example 7 EX23 represent the increased number of defective products in comparison to Comparative Example 5 CO21, Comparative Example 6 CO22, and Comparative Example 7 CO23, whereas Example 4 EX14 represents the decreased number of defective products in comparison to Comparative Example 4 CO14. Accordingly, it may be confirmed that, when the width of the venting hole is about 15% or more of the width of the opening, the air trap may be prevented in the opening. When the width of the venting hole is less than about 10% of the width of the opening, it may be assumed that the effect of preventing air trap by the venting hole is hardly exhibited or the amount of air remaining trapped in the relatively small venting hole is rather increased.

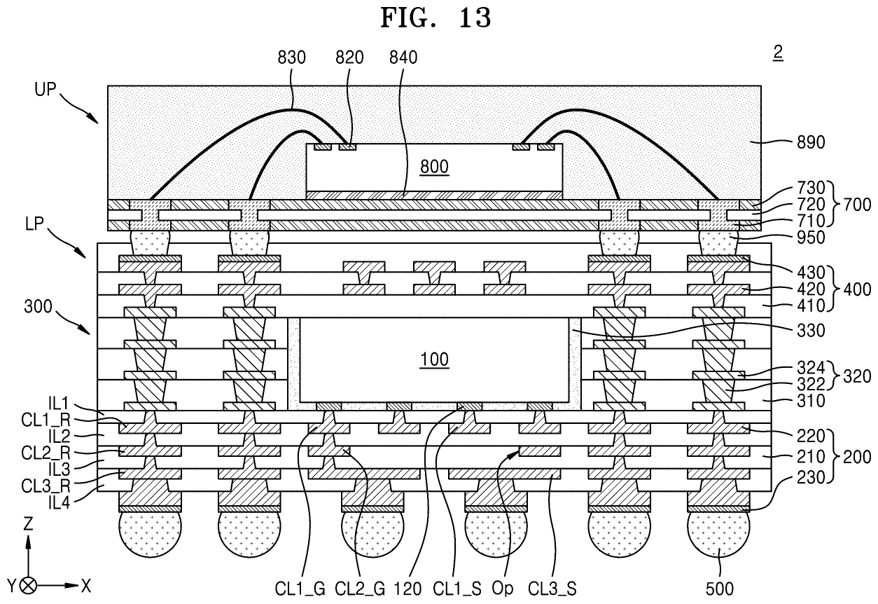

FIG. 13 is a cross-sectional view illustrating an example of a semiconductor package 2.

Referring to FIG. 13, the semiconductor package 2 may be a package-on-package (POP) including a lower package LP and an upper package UP attached on the lower package LP.

The lower package LP may include a first redistribution structure 200, a second redistribution structure 400 on the first redistribution structure 200, a semiconductor chip 100 arranged between the first redistribution structure 200 and the second redistribution structure 400, and a connection structure 300 arranged between the first redistribution structure 200 and the second redistribution structure 400 and surrounding the semiconductor chip 100. The lower package LP may include the semiconductor package 1 described with reference to FIGS. 1 to 11.

The upper package UP may be attached onto the second redistribution structure 400. The upper package UP may be electrically connected to a plurality of second redistribution patterns 420 of the second redistribution structure 400. For example, the upper package UP may be connected to the plurality of top surface connection pads 430. For example, a plurality of package connection terminals 950 may be arranged between the upper package UP and the plurality of upper surface connection pads 430. For example, the plurality of package connection terminals 950 may be attached to the plurality of top surface connection pads 430. The plurality of package connection terminals 950 may electrically connect the lower package LP and the upper package UP to each other. In some implementations, each of the plurality of package connection terminals 950 may be a bump, a solder ball, or the like.

The upper package UP includes a package board 700 and an auxiliary semiconductor chip 800 mounted on the package board 700. The auxiliary semiconductor chip 800 may be mounted on the package board 700 by a plurality of auxiliary chip pads 820 provided on the top surface of the auxiliary semiconductor chip 800.

The auxiliary semiconductor chip 800 may be a memory semiconductor chip. For example, the auxiliary semiconductor chip 800 may be a DRAM chip, an SRAM chip, a flash memory chip, an EEPROM chip, a PRAM chip, a MRAM chip, or an RRAM chip.

In some implementations, the auxiliary semiconductor chip 800 is electrically connected to the package board 700 through a plurality of bonding wires 830 connected to the plurality of auxiliary chip pads 820, and may be mounted on the package board 700 using a die attach film (DAF) 840. In some implementations, the upper package UP may include a plurality of auxiliary semiconductor chips 800 spaced apart from each other in a horizontal direction, or may also include a plurality of auxiliary semiconductor chips 800 stacked in a vertical direction. Alternatively, the upper package UP may include a plurality of auxiliary semiconductor chips 800 electrically connected through a through electrode and stacked in a vertical direction. Alternatively, the auxiliary semiconductor chip 800 may be mounted on the package board 700 in a flip chip manner.

The package board 700 may be a printed circuit board. For example, the package board 700 may be a double-sided printed circuit board or a multi-layer printed circuit board. The package board 700 may include at least one base insulation layer 710 and a plurality of wiring patterns 720. The plurality of wiring patterns 720 may include a portion arranged on a bottom surface of the base insulation layer 710, a portion arranged on a top surface of the base insulation layer 710, and a portion penetrating the base insulation layer 710. In some implementations, the package board 700 may include a solder resist layer 730 arranged on each of the top and bottom surfaces of the base insulation layer 710. The plurality of package connection terminals 950 may be attached to portions arranged on the bottom surface of the base insulation layer 710, among the plurality of wiring patterns 720, and the plurality of bonding wires 830 may be connected to portions arranged on the top surface of the base insulation layer 710, among the plurality of wiring patterns 720.

In some implementations, the upper package UP may further include a package molding layer 890 surrounding the auxiliary semiconductor chip 800 and a plurality of bonding wires 830 on the package board 700. For example, the package molding layer 890 may be a molding member including an epoxy mold compound (EMC).

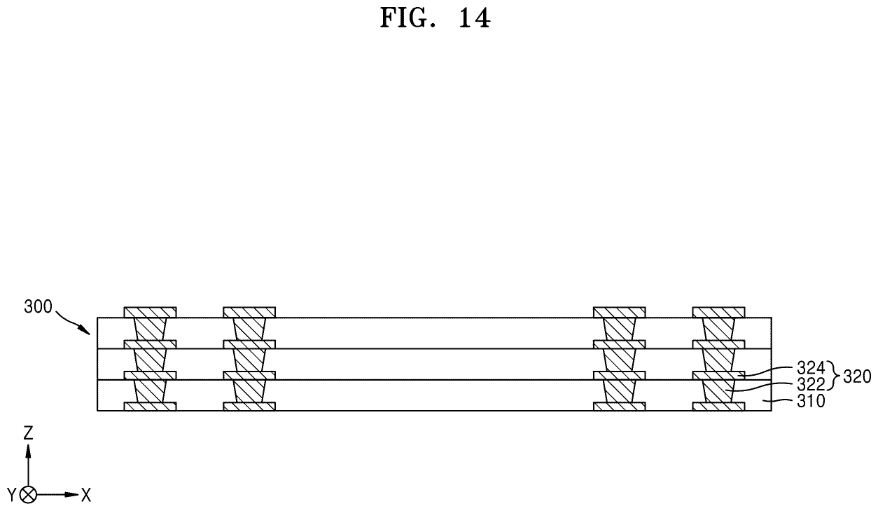

FIGS. 14 to 18, 19A to 19E, and 20 are schematic cross-sectional views illustrating an example of a method of manufacturing a semiconductor package.

Referring to FIG. 14, a connection structure 300, including a base layer 310 and a plurality of connection vias 320, is prepared.

Each of the plurality of connection vias 320 may include a via portion 322 penetrating the base layer 310 and a connection pattern portion 324 arranged on the top surface of the base layer 310 and integrally connected to the via portion 322.

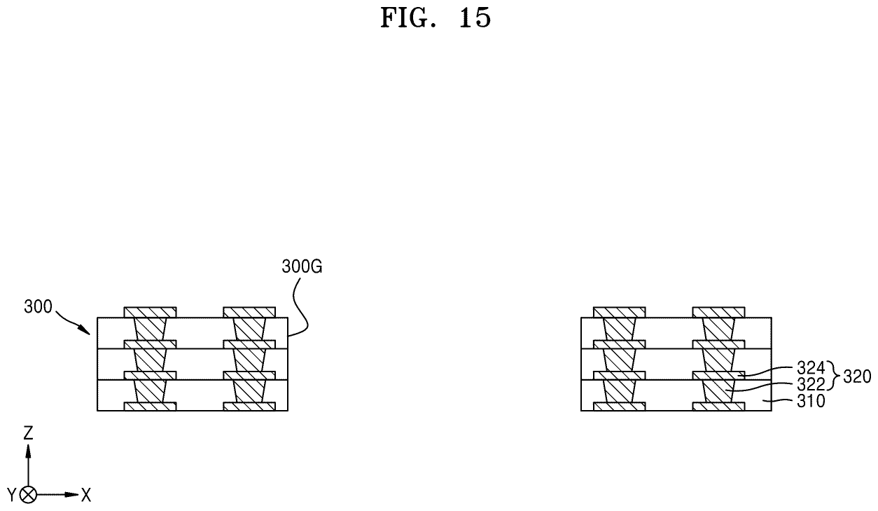

Referring to FIG. 15, a mounting space 300G penetrating from a top surface to a bottom surface of the connection structure 300 is formed. To form the mounting space 300G, dry etching, wet etching, screen printing, drill bits, or laser drilling processes may be used. In some implementations, the mounting space 300G may be formed in a central region of the connection structure 300 in a plan view.

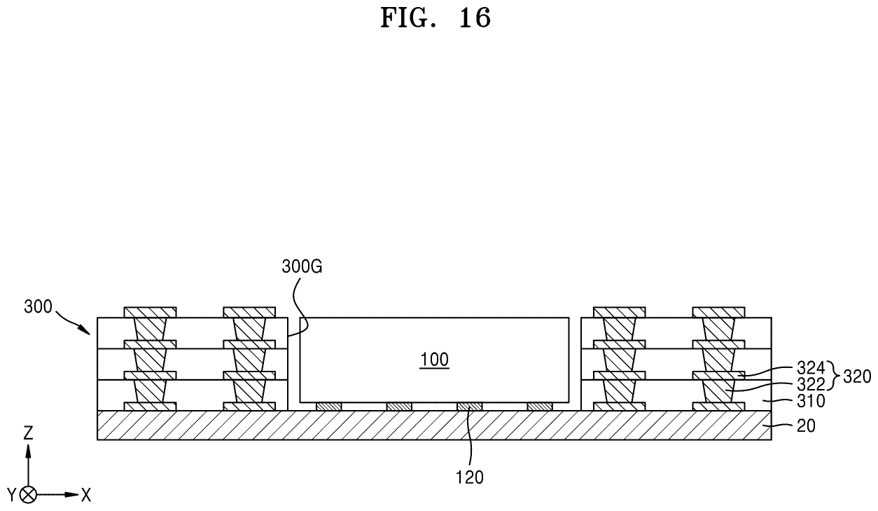

Referring to FIG. 16, after attaching the connection structure 300 on a support film 20, the semiconductor chip 100 is placed in the mounting space 300G. The semiconductor chip 100 may be attached onto the support film 20 in the mounting space 300G. The support film 20 may be an adhesive film, but is not limited thereto. For example, the support film 20 may be a dicing film. The semiconductor chip 100 has a face-down arrangement in which a first surface on which a plurality of lower chip pads 120 are arranged faces the support film 20 and may be attached to the support film 20.

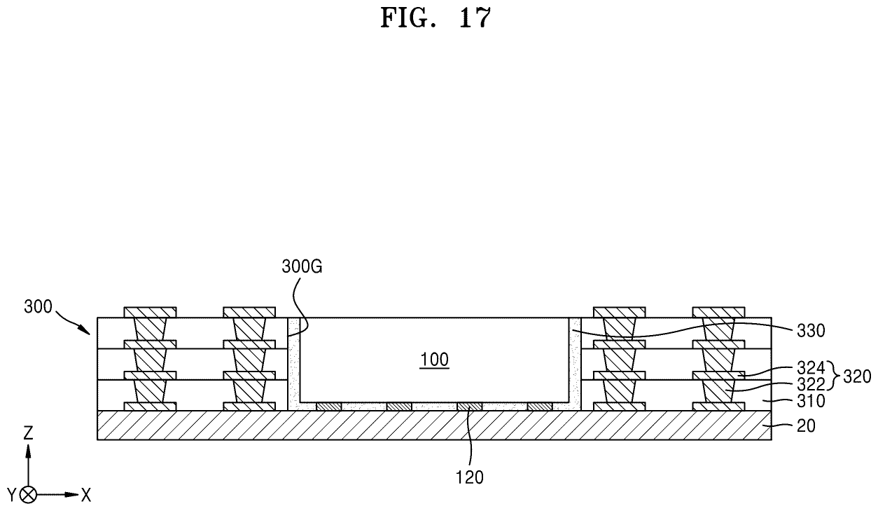

Referring to FIG. 17, a filling insulation layer 330 may be formed to fill the mounting space 300G. The filling insulation layer 330 may fill a space between the semiconductor chip 100 and the base layer 310 arranged in the mounting space 300G. In some implementations, the filling insulation layer 330 may be formed on the support film 20 to cover the side surface and the top surface of the semiconductor chip 100 and fill all of the mounting space 300G.

After forming the filling insulation layer 330, the support film 20 may be removed.

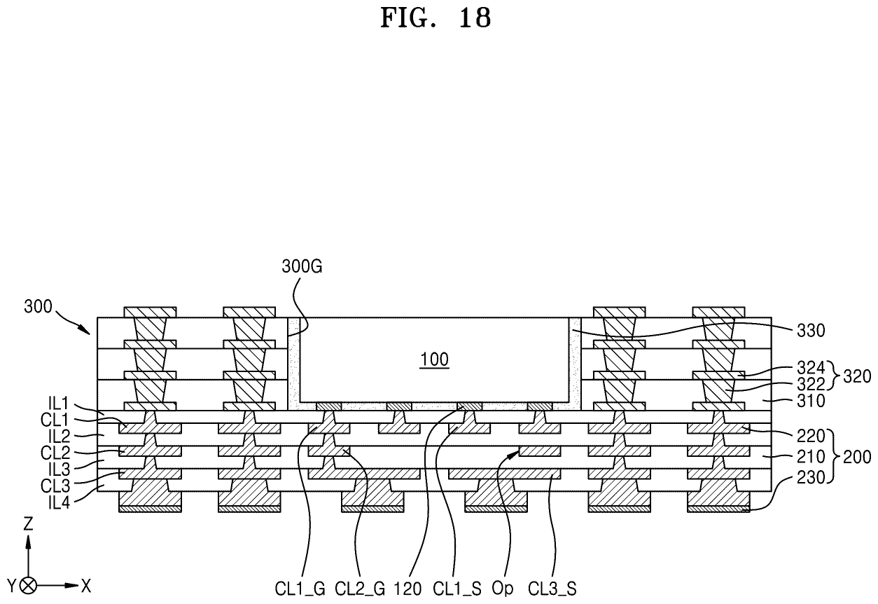

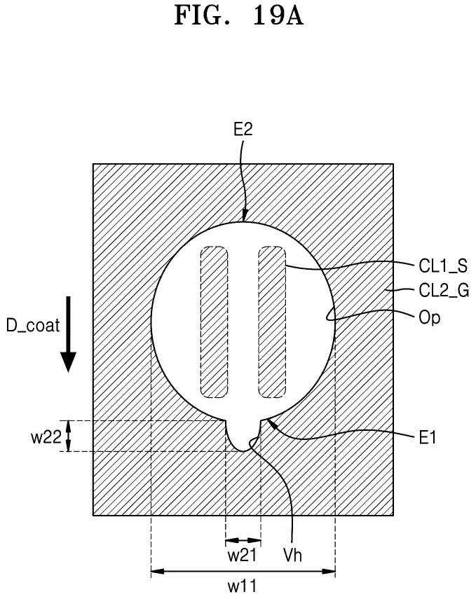

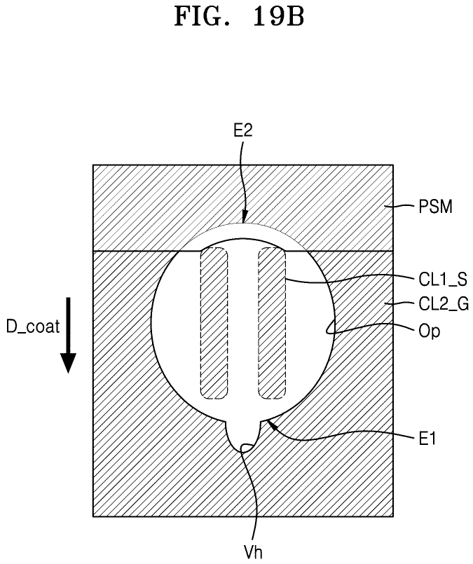

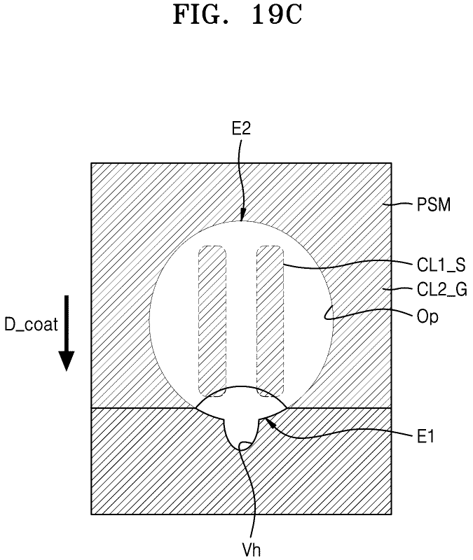

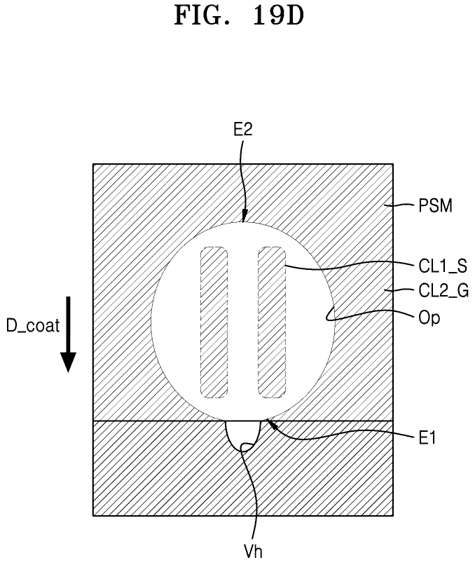

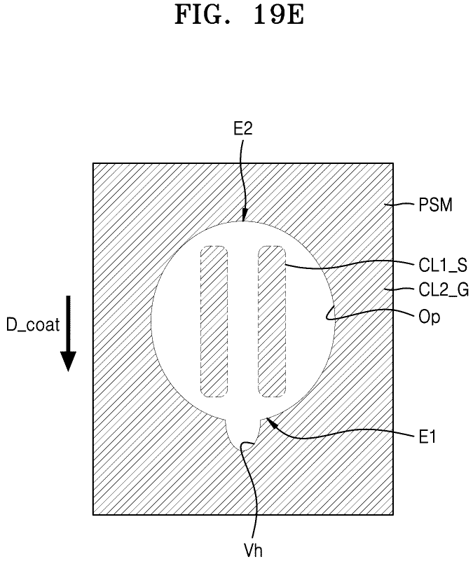

Referring to FIGS. 18, 19A to 18E, a first redistribution structure 200 is formed on the bottom surfaces of the semiconductor chip 100, the connection structure 300, and the filling insulation layer 330. The first redistribution structure 200 may be formed on the semiconductor chip 100, the connection structure 300, and the filling insulation layer 330 after vertically inverting the resultant of FIG. 17 so that the bottom surfaces of the semiconductor chip 100, the connection structure 300, and the filling insulation layer 330 face upward.

The first redistribution insulation layer 210 may be formed by coating or applying a photosensitive polymer material coated, and curing the coated photosensitive polymer material. Each of the first redistribution insulation layers 210 may include first to fourth insulation layers IL1, IL2, IL3, and IL4 formed by coating, exposure, development, and curing processes of such a photosensitive polymer material.

For example, an exposure process may be performed on a portion of the first insulation layer IL1, the portion of the first insulation layer IL1 may be removed by a development process, the portion of the first insulation layer IL1 may be removed by a development process, and then the first insulation layer IL1 may be cured by a curing process.

Thereafter, a plurality of first conductive lines CL1 may be formed on the first insulation layer IL1. The plurality of first conductive lines CL1 may be formed using sputtering, physical vapor deposition, electron beam evaporation, an electroplating process, or an electroless plating process.

By repeating these processes, a second insulation layer IL2 is formed on the first insulation layer IL1 to cover the plurality of first conductive lines CL1, a plurality of second conductive lines CL2 are formed on the second insulation layer IL2, and a third insulation layer IL3 is formed to cover the plurality of second conductive lines CL2 on the second insulation layer IL2.

FIGS. 19A to 19E schematically illustrate a coating process of a photosensitive polymer material for forming the third insulation layer IL3 covering the plurality of second conductive lines CL2 in chronological order.

As illustrated in FIG. 19A, each of the plurality of second conductive lines CL2 may include a second ground line CL2_G, and the second ground line CL2_G may include an opening Op and a venting hole Vh. The opening Op may have a relatively wide first width w11, and the venting hole Vh may be arranged to communicate with the first end portion E1 of the opening Op and may have a second width w21 smaller than the first width w11. A step may occur between the top surface of the second ground line CL2_G and the bottom surface of the opening Op due to the opening Op.

Referring to FIG. 19B, a photosensitive polymer material PSM may be applied or coated in a coating direction D_coat. In some implementations, the coating process of the photosensitive polymer material PSM may include slit coating. In the coating process, a photosensitive polymer material PSM may be coated or applied in the coating direction D_coat from the second end portion E2 of the opening Op toward the first end portion E1 of the opening Op.

FIG. 19C illustrates, as an example, a state in which the photosensitive polymer material PSM fills the remaining portion of the opening Op, leaving only a portion adjacent to the first end portion E1 of the opening Op. A difference in speed of the photosensitive polymer material PSM may occur due to a step between the top surface of the second ground line CL2_G and the bottom surface of the opening Op, and accordingly, the surface of the photosensitive polymer material PSM arranged inside the opening Op may move later than the surface of the photosensitive polymer material PSM on the top surface of the second ground line CL2_G. As shown in FIG. 19C, a portion of the opening Op adjacent to the first end portion E1 and the inside of the venting hole Vh may be in a state that is not filled with the photosensitive polymer material PSM.

FIG. 19D illustrates a state in which the photosensitive polymer material PSM completely fills a portion adjacent to the first end portion E1 of the opening Op and is not filled in the venting hole Vh. All of the air inside the opening Op may be discharged through the venting hole Vh.

FIG. 19E illustrates, for example, a state in which the photosensitive polymer material PSM completely fills the inside of the venting hole Vh and covers the entire top surface of the second ground line CL2_G. As shown in FIG. 19E, the photosensitive polymer material PSM may completely fill the inside of the opening Op, all air is discharged through the venting hole Vh, and the inside of the venting hole Vh may also be completely filled with the photosensitive polymer material PSM or only a little amount of air may remain inside the venting hole Vh.

Referring back to FIG. 18, a plurality of third conductive lines CL3 may be formed on the third insulation layer IL3, and a fourth insulation layer IL4 may be formed on the third insulation layer IL3 to cover the plurality of third conductive lines CL3.

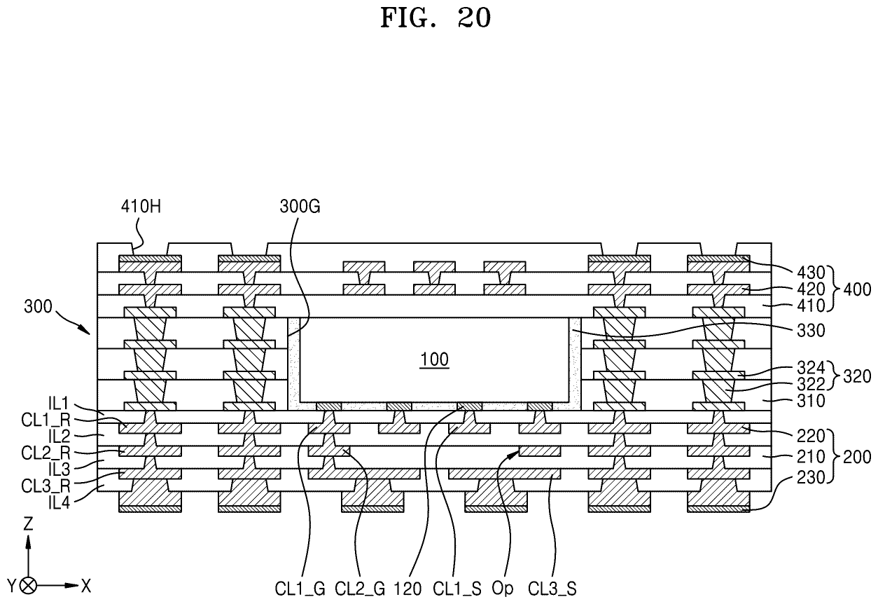

Referring to FIG. 20, the second redistribution structure 400 is formed on the top surfaces of the connection structure 300 and the filling insulation layer 330. After forming the first redistribution structure 200, the second redistribution structure 400 may be formed on the connection structure 300 and the filling insulation layer 330 by vertically inverting the resultant first redistribution structure 200 such that the top surfaces of the connection structure 300 and the filling insulation layer 330 face upward and the first redistribution structure 200 faces downward.

Thereafter, as shown in FIG. 1, the semiconductor package 1 may be formed by attaching the plurality of external connection terminals 500 to the plurality of bottom surface connection pads 230.

In general, when a photosensitive polymer material is applied to a redistribution line pattern having a relatively large opening, a step may occur due to a relatively high height of the redistribution line pattern. A difference in coating speed may occur due to the step, and the inside of the opening may not be completely filled by the photosensitive polymer material, and air may be trapped, and thus air may remain in the photosensitive polymer material. The trapped air may cause voids or cracks in the redistribution insulation layer, or may cause a defect in a subsequent redistribution line pattern.

However, according to the method of manufacturing the semiconductor package 1 described above, the inside of the opening Op may be completely filled with a photosensitive polymer material by the venting hole Vh communicating with the first end portion E1 of the opening Op, and air trapping inside the opening Op may be minimized or prevented. Therefore, the semiconductor package 1 may have excellent reliability.

The semiconductor package according to the present disclosure includes a signal line and a ground line arranged in a redistribution structure, and the ground line may include an opening vertically overlapping the signal line and a venting hole communicating with an end portion of the opening. In the process of forming a redistribution insulation layer to fill the opening by coating a photosensitive polymer material, the venting hole may prevent the air trap from remaining in the opening and improve the reliability of the redistribution structure.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been particularly shown and described with reference to implementations thereof, it will be understood that various changes in form and details may be made therein without departing from the spirit and scope of the following claims.

What is claimed is:

1. A semiconductor package comprising:
a redistribution structure including a first surface and a second surface; and
a semiconductor chip on the first surface of the redistribution structure,
wherein the redistribution structure includes:
a plurality of first conductive lines at a first vertical level and including a first signal line; and
a plurality of second conductive lines at a second vertical level different from the first vertical level of the plurality of first conductive lines, the plurality of second conductive lines including a ground line that is electrically isolated from the first signal line,
wherein the ground line defines:
an opening extending through the ground line at a position vertically overlapping the first signal line, the opening including a first end portion having a first width in a first horizontal direction; and
a venting hole in communication with the first end portion of the opening, the venting hole having a second width smaller than the first width in the first horizontal direction.

2. The semiconductor package of claim 1, wherein the second width is 15% to 30% of the first width.

3. The semiconductor package of claim 1, wherein
the venting hole has a third width in a second horizontal direction, the second horizontal direction crossing the first horizontal direction, and
the third width is 50% or more of the second width.

4. The semiconductor package of claim 1, wherein the venting hole has a planar shape of at least one of a circle, a triangle, a rectangle, or a rounded rectangle.

5. The semiconductor package of claim 1, wherein
the opening has a first area in a plan view,
the venting hole has a second area in the plan view, and
the second area is in a range of 5% to 30% of the first area.

6. The semiconductor package of claim 1, wherein
the first signal line includes a pair of signal line patterns, and
the pair of signal line patterns are spaced apart from each other in a lateral direction.

7. The semiconductor package of claim 6, wherein the opening overlaps the pair of signal line patterns vertically.

8. The semiconductor package of claim 1, wherein
the plurality of first conductive lines comprise a first redistribution line spaced apart from the first signal line, and
the plurality of second conductive lines comprise a second redistribution line spaced apart from the ground line.

9. The semiconductor package of claim 1, wherein the redistribution structure includes:
a redistribution insulation layer covering the plurality of first conductive lines and the plurality of second conductive lines, and
a portion of the redistribution insulation layer is provided inside the opening and the venting hole.

10. The semiconductor package of claim 1, wherein the venting hole comprises:
a first venting hole in communication with the first end portion of the opening; and
a second venting hole in communication with the first end portion of the opening, the second venting hole being spaced apart from the first venting hole in a lateral direction.

11. The semiconductor package of claim 1, comprising:
a connection structure on the first surface of the redistribution structure, the connection structure including a mounting space in which the semiconductor chip is mounted; and
an external connection terminal attached to the second surface of the redistribution structure, the external connection terminal being electrically connected with the redistribution structure.

12. A semiconductor package comprising:
a redistribution structure including a first surface and a second surface;
a semiconductor chip on the first surface of the redistribution structure; and
an external connection terminal on the second surface of the redistribution structure,
wherein the redistribution structure includes:
a plurality of first conductive lines at a first vertical level lower than a vertical level of the first surface of the redistribution structure;
a first redistribution insulation layer covering a plurality of bottom surfaces of the plurality of first conductive lines;
a plurality of second conductive lines on a bottom surface of the first redistribution insulation layer, the plurality of second conductive lines being at a second vertical level lower than the first vertical level; and
a second redistribution insulation layer on the bottom surface of the first redistribution insulation layer, the second redistribution insulation layer covering a plurality of bottom surfaces of the plurality of second conductive lines,
wherein at least one second conductive line of the plurality of second conductive lines defines:
an opening extending through the at least one second conductive line, the opening including a first end portion having a first width in a first horizontal direction; and
a venting hole in communication with the first end portion of the opening, the venting hole having a second width smaller than the first width of the opening.

13. The semiconductor package of claim 12, wherein a portion of the second redistribution insulation layer is provided inside the opening and inside the venting hole.

14. The semiconductor package of claim 12, wherein
the plurality of first conductive lines include a pair of signal line patterns, and
the opening overlaps the pair of signal line patterns vertically.

15. The semiconductor package of claim 14, wherein the second width is 15% to 30% of the first width.

16. The semiconductor package of claim 15, wherein
the venting hole has a third width in a second horizontal direction, the second horizontal direction crossing the first horizontal direction, and
the third width is 50% or more of the second width.

17. The semiconductor package of claim 12, wherein
the opening has a first area in a plan view,
the venting hole has a second area in the plan view, and
the second area is in a range of 5% to 30% of the first area.

18. A semiconductor package comprising:
a first redistribution structure;
a semiconductor chip on a top surface of the first redistribution structure;
a connection structure on the top surface of the first redistribution structure and on at least one side of the semiconductor chip;
a second redistribution structure on the semiconductor chip and the connection structure; and
a solder ball on a bottom surface of the first redistribution structure,
wherein the first redistribution structure includes:
a plurality of first conductive lines including a first signal line;
a first redistribution insulation layer covering the plurality of first conductive lines, the first redistribution insulation layer including a first photosensitive polymer;
a plurality of second conductive lines at a vertical level lower than the plurality of first conductive lines, the plurality of second conductive lines including a ground line that is electrically insulated from the first signal line; and
a second redistribution insulation layer covering the plurality of second conductive lines, the second redistribution insulation layer including a second photosensitive polymer,
wherein the ground line includes:
an opening extending through the ground line at a position vertically overlapping the first signal line, the opening including a first end portion having a first width in a first horizontal direction;
a venting hole in communication with the first end portion of the opening, the venting hole having a second width smaller than the first width in the first horizontal direction; and
a pair of signal line patterns, wherein the opening overlaps the pair of signal line patterns vertically.

19. The semiconductor package of claim 18, wherein
the second width is 15% to 30% of the first width,
the venting hole has a third width in a second horizontal direction, the second horizontal direction crossing the first horizontal direction, and
the third width is 50% or more of the second width.

20. The semiconductor package of claim 18, wherein
the opening has a first area in a plan view,
the venting hole has a second area in the plan view, and
the second area is in a range of 5% to 30% of the first area.
